(19) United States
(12) Patent Application Publication
(10) Pub. No.: US 2011/0147937 A1
(43) Pub. Date: Jun. 23, 2011

(54) METHOD OF MANUFACTURING SEMICONDUCTOR DEVICE AND SEMICONDUCTOR DEVICE

(76) Inventor: Hiroshi KUBOTA, Yokkaichi (JP)

(21) Appl. No.: 12/846,213

(22) Filed: Jul. 29, 2010

(30) Foreign Application Priority Data
Dec. 17, 2009 (JP) 2009-286484

(51) Int. Cl. H01L 23/522; H01L 21/768

(52) U.S. Cl. 257/751; 438/643; 257/E21.584; 257/E23.142

(57) ABSTRACT

In one exemplary embodiment, a method of manufacturing a semiconductor device is disclosed in which a damascene interconnect is formed above an underlying insulating film. The method includes forming an interconnect insulating film above the underlying insulating film such that a film density of the interconnect insulating film is relatively greater at a lower side thereof and relatively less at an upper side thereof. The interconnect insulating film is anisotropically dry etched to form an interconnect trench. The interconnect trench is wet etched such that an upper portion of a vertical cross section thereof exhibits a positive taper. A barrier metal film is formed along an inner surface of the interconnect trench including the positive taper. Further, the interconnect trench is filled with an interconnect conductor by plating over the barrier metal film.

### CROSS-REFERENCE TO RELATED APPLICATION(S)

This application is based upon and claims the benefit of priority from the prior Japanese Patent Application No. 2009-286484, filed on, Dec. 17, 2009, the entire contents of which are incorporated herein by reference.

### FIELD

Exemplary embodiments disclosed herein generally relate to a method of manufacturing semiconductor device provided with damascene interconnect and a semiconductor device manufactured by such method.

### BACKGROUND

Damascene process is one of the techniques used in forming interconnect patterns in semiconductor device manufacturing in which copper (Cu) is used as the metal conductive layer. In a damascene process, structures such as barrier metal and copper seed are formed by sputtering after preparing interconnect trenches. Because the above described structures need to be formed over the sidewalls of the interconnect trenches, bias is applied on the semiconductor substrate side to allow film formation by re-sputtering.

In 35 nm and denser interconnect patterns where the interconnect trenches are narrow, the trench openings are often blocked by re-sputter film growing in the proximity of the trench openings before barrier metal and copper seed have a chance to grow to their required thickness on the sidewalls of the trenches. The lack of growth of copper seed ultimately leads to side void formation because it introduces copper plating failures in the subsequent copper plating step. Side voids adversely affect the trench fill capability, and thus, need to be eliminated for proper device performance.

One solution to the above described problem may be tapering the sidewalls of the interconnect trenches when forming the trenches by RIE (Reactive Ion Etching). A tapered sidewall would allow sufficient film growth on the sidewall with relatively less bias applied on the substrate side to improve the trench fill capability. In order to taper the sidewalls of the interconnect trenches, RIE needs to be controlled to leave RIE deposits on the sidewalls of the interconnect trenches. Ina 35 nm and denser design rule, however, the RIE deposit inevitably develops on the bottom of the trenches which results in premature etching. Thus, it has been technically difficult to taper the sidewalls of the interconnect trenches by RIE.

### BRIEF DESCRIPTION OF THE DRAWINGS

FIG. 1 is a schematic cross sectional view of a semiconductor device according to one exemplary embodiment;

FIG. 2 is a schematic block diagram of a dual frequency excited CVD (Chemical Vapor Deposition) apparatus;

FIGS. 3A to 3G are schematic cross sectional views indicating different phases of the manufacturing steps;

FIG. 4A is a chart indicating the correlation between the output level of a low-frequency power supply and film density; and

FIG. 4B is a chart indicating the correlation between film density and wet etching speed.

### DETAILED DESCRIPTION

In one exemplary embodiment, a method of manufacturing a semiconductor device is disclosed in which a damascene interconnect is formed above an underlying insulating film. The method includes forming an interconnect insulating film above the underlying insulating film such that a film density of the interconnect insulating film is relatively greater at a lower side thereof and relatively less at an upper side thereof. The interconnect insulating film is anisotropically dry etched to form an interconnect trench. The interconnect trench is wet etched such that an upper portion of a vertical cross section thereof exhibits a positive taper. A barrier metal film is formed along an inner surface of the interconnect trench including the positive taper. Further, the interconnect trench is filled with an interconnect conductor by plating over the barrier metal film.

In one exemplary embodiment, a semiconductor device is disclosed that includes an underlying insulating film, an interconnect insulating film, an interconnect trench, a barrier metal film, and an interconnect conductor. The interconnect insulating film is formed above the underlying insulating film. The interconnect insulating film includes a film density being relatively greater at a lower side thereof and relatively less at an upper side thereof. An interconnect trench is formed into the interconnect insulating film. The interconnect trench includes greater width at an upper side thereof compared to a lower side thereof. A barrier metal film is formed along an inner surface of the interconnect trench. Further, an interconnect conductor is filled into the interconnect trench over the barrier metal film.

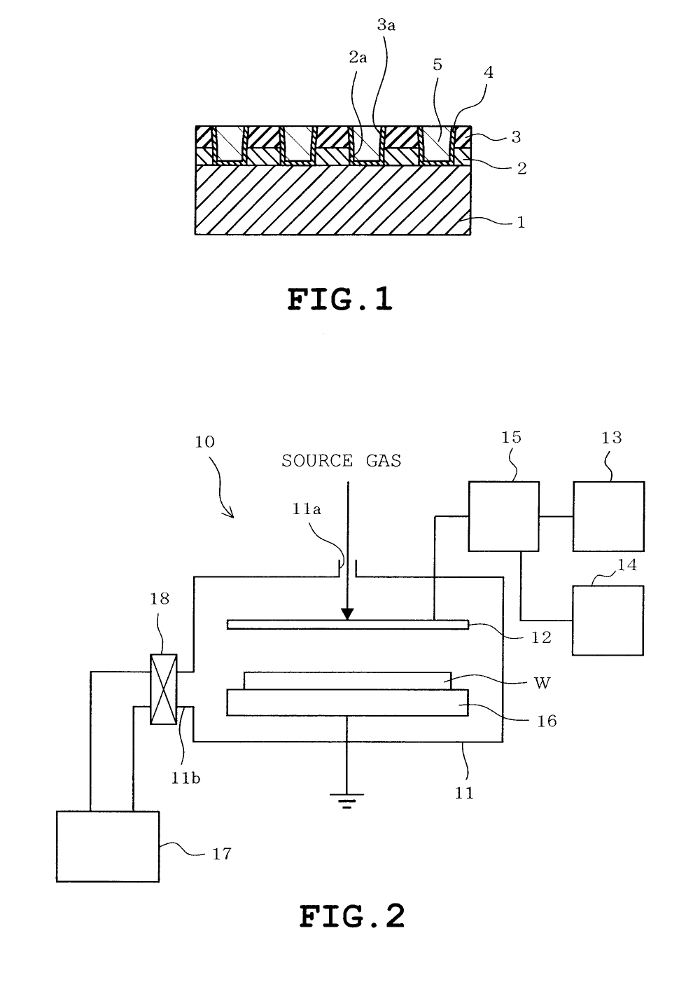

One exemplary embodiment will be described with reference to FIGS. 1 to 4. Elements that are identical or substantially identical across the figures are identified with identical or similar reference symbols. It is to be further noted that the figures are schematic and do not reflect the actual measurements of the features such as the relation between thickness and planar dimensions and the ratio of thickness between each layer.

FIG. 1 is a vertical cross sectional view of interconnect structures formed by damascene technique. As shown in FIG. 1, plasma TEOS (tetraethyl orthosilicate) oxide film 1 is formed above the semiconductor substrate, one typical example of which may be a silicon substrate. Semiconductor substrate has semiconductor elements such as memory cell transistors and peripheral circuit transistors implemented on it. Though not shown, plasma TEOS oxide film 1 has via plugs and contact plugs embedded in it wherever required. Damascene interconnect structure formed above plasma TEOS oxide film 1 is located at portions where connection is established between the neighboring semiconductor elements, and where electric connection is established with via plug provided through the underlying interconnect layer.

Above plasma TEOS oxide film 1, plasma silicon nitride film (P-SiN) 2 is formed that serves as a stopper when forming the interconnect trench. Further above plasma silicon nitride film (P-SiN) 2, plasma TEOS oxide film 3 is formed that serves as an interconnect insulating film. Plasma TEOS oxide film 3 is formed so as to increase its density toward its bottom surface that contacts the underlying plasma silicon nitride film 2, meaning that the upper portion of plasma TEOS oxide film 3 has less density at its upper portion compared to its lower portion. Plasma TEOS oxide film 3 is formed by a later described double frequency excited plasma CVD apparatus. Because Plasma TEOS oxide film 3 is formed to vary its density with film thickness as described above, dielectric constant which is one of the parameters for evaluating the electric properties of a semiconductor device increases as the film thickness increases, meaning that the dielectric constant is relatively greater at greater thickness (lower portion) of plasma TEOS oxide film 3, whereas the dielectric constant is relatively less at less thickness (upper portion) of plasma TEOS oxide film 3.

Plasma TEOS oxide film 3 and plasma silicon nitride film 2 have interconnect trenches 2a and 3a formed through them. Interconnect trench 3a formed through plasma TEOS oxide film 3 is formed such that width of its upper trench opening is greater than its lower trench opening to exhibit a positive taper profile. Interconnect trench 2a of plasma silicon nitride film 2, on the other hand, is substantially uniform in width regardless of its elevation, meaning that the trench is not tapered.

Within interconnect trenches 3a and 2a, thin barrier metal film 4 is lined along their inner surfaces and copper (Cu) film 5 is further formed over barrier metal film 4 to fill trenches 3a and 2a.

According to the above described configuration, dielectric constant of plasma TEOS oxide film 3 is controlled to be relatively lower at its upper portion as compared to its lower portion, and thus, coupling capacitance with the adjacent Cu film 5 serving as the conducting element of the interconnect structure is reduced. Further, because interconnect trench 3a is tapered, interconnect resistance originating from copper film 5 is reduced. The advantages offered by the tapered profile in terms of device manufacture will be discussed in the following description of the manufacturing steps.

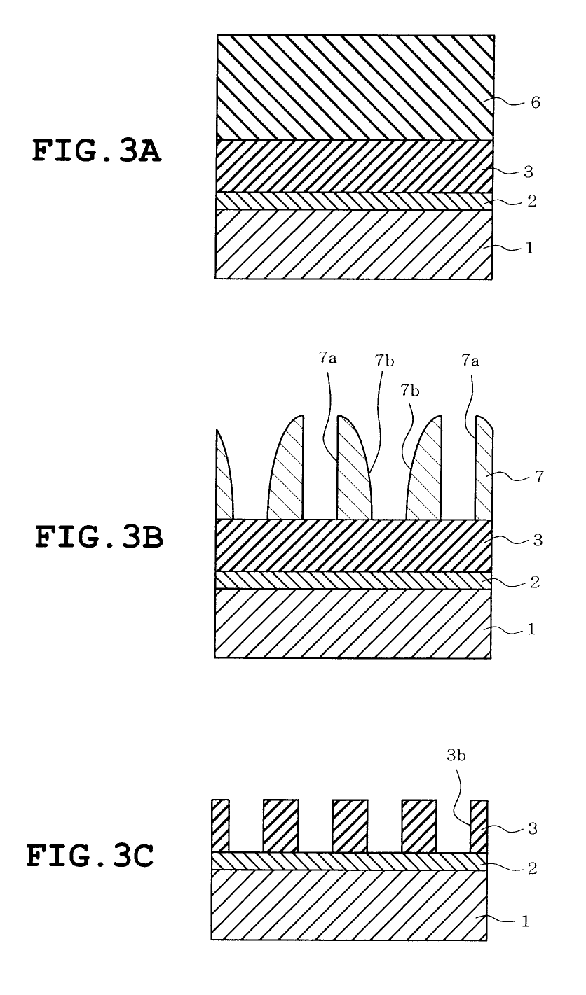

Next, the manufacturing steps of the above described configuration are described with reference to FIGS. 2 to 4.

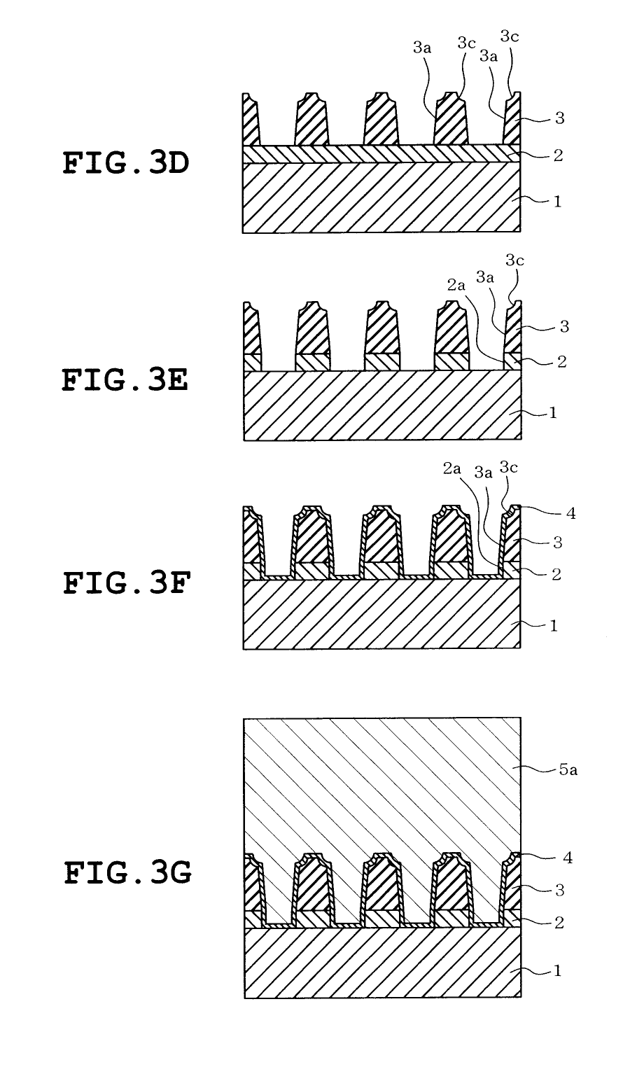

Referring to FIG. 3A, plasma TEOS oxide film 1 serving as the underlying insulating film is formed above the features such as the semiconductor substrate. Though not shown, elements for establishing connection with damascene interconnect structure such as a contact plug and a via plug are formed through plasma TEOS oxide film 1. Plasma TEOS oxide film 1 is treated by CMP (Chemical Mechanical Polishing) to expose the upper surfaces of the contact plug and the via plug.

On top of plasma TEOS oxide film 1, plasma silicon nitride film 2 is formed that serves as a stopper film during RIE for forming the interconnect trenches. Then, plasma TEOS oxide film 3 is further formed on top of plasma silicon nitride film 2. As described earlier, plasma TEOS oxide film 3 is formed such that its density is maximized at its lower surface side and gradually reduced toward the upper side so as to be minimized at its upper surface.

The steps involved in forming plasma TEOS oxide film 3 is described with reference to FIG. 2. FIG. 2 provides the overall configuration of dual-frequency excitation plasma CVD apparatus 10 used in forming plasma TEOS oxide film 3. The reaction chamber of the apparatus is configured by metal chamber 11 which takes in source gas fed from MFC (Mass Flow Controller) in controlled amounts through source gas intake 11a. Then, the source gas is dispersed evenly onto the work piece through RF electrode 12 also serving as gas dispersion plate. Examples of the source gas are silane (SiH₄) gas, nitrous oxide (N₂O) gas, nitrogen (N₂) gas, and ammonia (NH₃) gas, etc.

Power is supplied to RF electrode 12 from high-frequency power supply 13 and low-frequency power supply 14 by way of matching circuit 15. High-frequency power supply 13 has a capacity to output high-frequency waves ranging between 10 to 30 MHz and is controlled to output 13.56 MHz in the present exemplary embodiment. Low-frequency power supply 12, on the other hand has a capacity to output low-frequency power supply ranging between 300 to 500 kHz and is preferably controlled to output low-frequency waves ranging between 350 to 450 kHz. Low-frequency power supply 14 is configured to be capable of varying the level of low-frequency waves during formation of plasma TEOS oxide film 3. Outputs of high-frequency power supply 13 and low-frequency power supply 14 are matched by matching circuit 15 and fed to RF electrode 12.

When power is supplied to RF electrode 12 from high-frequency power supply 13 and low frequency power supply 14, capacitance coupling occurs between RF electrode 12 and wafer stage electrode 16, which in turn produces electric power inside metal chamber 11 to generate plasma. Wafer stage electrode 16, being earthed, serves as a susceptor for placing silicon wafer W. Wafer stage electrode 16 is provided with a lift mechanism to allow control of clearance between silicon wafer W and RF electrode 12 located above it. Wafer stage electrode 16 further contains a heater for heating the overlying silicon wafer W to a predetermined temperature during film formation.

Metal chamber 11 is connected to dry pump 17 by way of a conduit which communicates with metal chamber 11 at connection lib. Throttle valve 18 is provided on one end of the conduit proximal to the connection 11b to allow the pressure inside metal chamber 11 to be reduced to vacuum or close to vacuum and maintain the pressure at the reduced level.

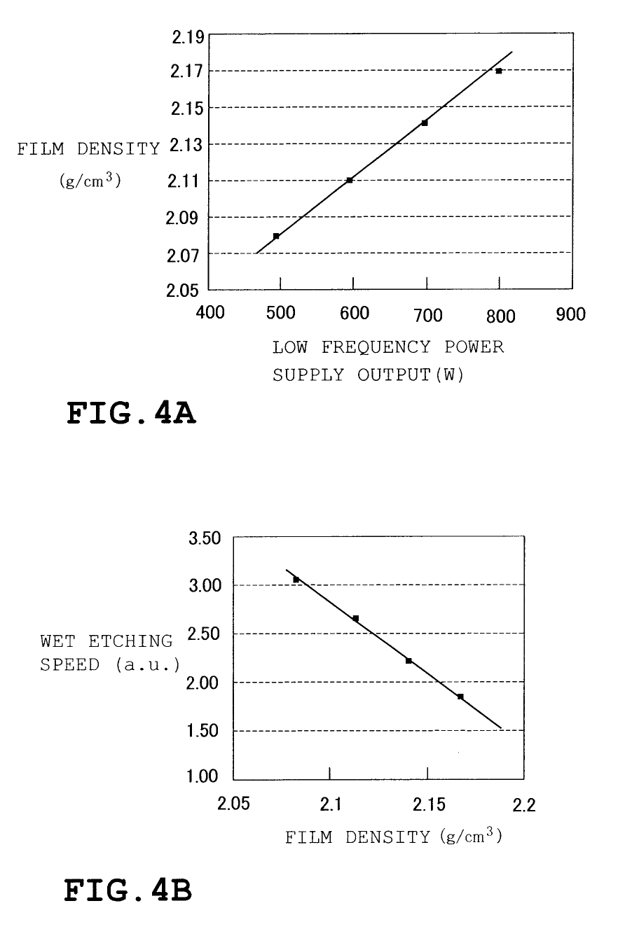

Dual-frequency excitation plasma CVD apparatus 10 configured as described above is responsible for the formation of plasma TEOS oxide film 3. To elaborate, the aforementioned low-frequency power supply 14 gradually reduces its level of output with time after initiating the formation of plasma TEOS oxide film 3. The density of plasma TEOS oxide film 3 decreases as the level of output of low-frequency power supply 14 decreases in a proportional correlation as exemplified in the chart of output (W) of low-frequency power versus film density (g/cm³) indicated in FIG. 4A. In contrast, the speed of wet etching of plasma TEOS oxide 3 increases as the film density decreases as exemplified in the chart of film density (g/cm³) versus wet etching speed (a.u.) indicated in FIG. 4B.

Thus, in forming plasma TEOS oxide film 3, because the output level of low-frequency power supply 14 is gradually reduced to vary the film density of plasma TEOS oxide film 3, the speed of wet etching can be controlled to be greater at relatively upper portion of plasma TEOS oxide film 3 when viewed in the direction of its thickness.

After forming plasma TEOS oxide film 3 as described above, interconnect trenches are formed through plasma TEOS oxide film 3. In the present exemplary embodiment, interconnect trenches are formed through plasma TEOS oxide film 3 by way of sidewall transfer process as will be described hereinafter.

Referring again to FIG. 3A, plasma silicon nitride film 6 is formed on top of plasma TEOS oxide film 3. Then, though not shown, plasma silicon nitride film 6 is patterned by photolithography and thereafter narrowed in width by a slimming process to form a core material pattern.

Next, though not shown, an amorphous silicon film is formed in a predetermined thickness so as to cover the core material pattern. The amorphous silicon film is then formed into a spacer that is later used as a mask in RIE for forming interconnect trenches. Then, by selectively removing the core material pattern, transfer pattern 7 shown in FIG. 3B is obtained. Transfer pattern 7 has surface 7a that faces core material pattern and surface 7b that does not face core material pattern on the opposite side of surface 7a. Thus, transfer pattern 7 is asymmetrical as viewed in FIG. 3B.

Referring to FIG. 3C, using transfer pattern 7 as a mask, plasma TEOS oxide film 3 is selectively etched by RIE until the upper surface of plasma silicon nitride film 2 is exposed to form interconnect trench 3b. The sidewall of interconnect trench 3b formed through plasma TEOS oxide film 3 is etched so as to be substantially upright. Then, transfer pattern 7 used as the mask in RIE is removed by choline based wet etching

Referring now to FIG. 4D, interconnect trench 3b is tapered by wet etching to define interconnect trench 3a. Because the film density of plasma TEOS oxide film 3 is controlled to decrease toward its upper side, etching progresses at higher speed in the upper side where the film density is relatively less, whereas in the lower side where the film density is relatively greater, etching progresses at lower speed. Interconnect trench 3a can be tapered as illustrated in FIG. 4D by utilizing the above described behavior of wet etching correlated with film density.

One exemplary composition of the wet etchant is 0.1 to 10 wt % (weight percent) of dilute hydrofluoric (HF) acid with the preferred concentration being 0.1 to 0.3 wt % for better etching controllability. Because wet etching progresses isotropically, recess 3c is produced at the upper peripheral edges of interconnect trench 3a.

Then, as can be seen in FIG. 3E, plasma silicon nitride film 2 is further etched by RIE to expose plasma TEOS oxide film 1 serving as the underlying insulating film, thereby forming interconnect trench 2a communicating with interconnect trench 3a. Interconnect trench 2a is etched to exhibit a substantially upright sidewall.

Referring now to FIG. 3F, barrier metal film 4 serving as a diffusion barrier to copper film 5 is coated over the inner surfaces of interconnect trenches 3a and 2a by sputtering. Barrier metal film 4 also serves a seed in forming copper film 5. Because barrier metal film 4 needs to be formed over the sidewall of interconnect trench 3a, bias is applied on the substrate side as well during the sputtering process. The bias applied on the substrate side causes the film deposited on the bottom of the trench 2a to be re-sputtered onto the sidewalls of trenches 3a and 2a. Further, because interconnect trench 3a is tapered so that its width increases with elevation to define a positive taper profile, the growth of re-sputter film in the proximity of the upper mouth of interconnect trench 3a does not become an impediment to formation of barrier metal film 4 over the sidewall located further below the upper mouth or opening of interconnect trench 3a. Thus, sufficient amount of barrier metal film 4 can be grown over the sidewalls of interconnect trenches 3a and 2a.

Then, as shown in FIG. 3G, barrier metal film 4 is utilized as the copper seed film in plating copper plating film 5a over barrier metal film 4. At this instance, because barrier metal film 4 is sufficiently grown within interconnect trenches 3a and 2a, copper plating film 5a can be filled in interconnect trenches 3a and 2a without side voids.

Referring back to FIG. 1, overfilled copper plating film 5a formed as described above is removed and planarized by CMP such that it remains within interconnect trenches 3a and 2a. At this instance, because the upper portion of plasma TEOS oxide film 3 is polished away by CMP, recess 3c formed by wet etching the peripheral edges of interconnect trench 3a is also removed. Thus, copper film 5 serving as the conductive portion of the interconnect structure is finished into a damascene interconnect pattern.

According to the above described exemplary embodiment, dual frequency excitation plasma CVD apparatus 10 is configured to gradually vary the film density during the process of formation of plasma TEOS oxide film 3 serving as interconnect insulating film such that the film density is relatively greater at its lower side and relatively less in its upper side. Thus, when interconnect trench 3b formed through plasma TEOS oxide film 3 by RIE is wet etched by dilute HF acid, positively tapered interconnect trench 3a is obtained that increases its width with elevation. The tapered profile of interconnect trench 3a allows barrier metal film 4 to be sputtered sufficiently over the sidewall of interconnect trenches 3a and 2a to prevent occurrence of side voids when plating the copper plating film 5a, thereby providing a damascene interconnect structure configured by copper film 5 free of interconnect failures.

Because copper film 5 can be formed in a tapered profile, interconnect resistance can be reduced. Further, because plasma TEOS oxide film 3 located between the interconnect structures is configured to be relatively less in film density at its upper portion which also means that dielectric constant is relatively less at its upper portion, capacitance coupling of the interconnect structures can be prevented.

Exemplary embodiments of the present disclosure is not limited to the above described but may be modified or expanded as follows.

In the above described exemplary embodiment, the output level of low-frequency power supply 14 was controlled to gradually decrease to cause a continuous decrease in film density. However, the film density may be varied in discontinuous or stepped manner. For instance, the film density may be varied in multiple steps, such as significantly decreasing the film density only at the upper mouth of the interconnect trench. Different approaches maybe taken when continuously decreasing the film density such as varying the film density such that the width of the interconnect trench increases toward its upper side in a curved profile instead of a linear profile exemplified in the above described exemplary embodiment.

The concentration of dilute HF acid employed as the wet etchant may be varied within the range of 0.1 to 10 wt %. Lower concentration is advantageous in improving the controllability of wet etching, whereas higher concentration is advantageous in accelerating the wet etching to allow the interconnect trench processing to be completed in a shorter time span.

Damascene interconnect structure configured by copper film 5 may be replaced by other interconnect conductors. Further, after forming barrier metal film 4 over the inner surfaces of interconnect trenches 3a and 2a, additional copper film may be further sputtered over barrier metal film 4 by sputtering and barrier metal film 4 and copper film taken together may be utilized as the seed in filling copper plating film 5a into interconnect trenches 3a and 2a.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device in which a damascene interconnect is formed above an underlying insulating film, comprising:
forming an interconnect insulating film above the underlying insulating film such that a film density of the interconnect insulating film is relatively greater at a lower side thereof and relatively less at an upper side thereof;
anisotropically dry etching the interconnect insulating film to form an interconnect trench;
wet etching the interconnect trench such that an upper portion of a vertical cross section thereof exhibits a positive taper;
forming a barrier metal film along an inner surface of the interconnect trench including the positive taper; and
filling the interconnect trench with an interconnect conductor by plating over the barrier metal film.

2. The method according to claim 1, wherein forming the interconnect insulating film employs a plasma chemical vapor deposition technique excited by a low-frequency power supply and a high-frequency power supply, and wherein an output level of the low-frequency power supply is decreased with growth of the interconnect insulating film.

3. The method according to claim 1, wherein the interconnect insulating film comprises plasma tetraethyl orthosilicate oxide film.

4. The method according to claim 1, wherein the wet etching employs an etchant comprising 0.1 to 10.0 wt % of hydrofluoric acid.

5. The method according to claim 1, wherein the wet etching employs an etchant comprising 0.1 to 0.3 wt % of hydrofluoric acid.

6. The method according to claim 1, wherein the anisotropic dry etching forms the interconnect trench into the interconnect insulating film such that a sidewall of the interconnect trench is substantially upright.

7. The method according to claim 1, wherein forming the barrier metal film employs a sputtering technique that applies bias on the underlying insulating film side.

8. The method according to claim 1, wherein forming the interconnect insulating film above the underlying insulating film gradually varies the film density of the interconnect insulating film such that the film density of the interconnect insulating film is relatively greater at the lower side thereof and relatively less at the upper side thereof.

9. The method according to claim 1, wherein the underlying insulating film comprises plasma tetraethyl orthosilicate oxide film.

10. The method according to claim 1, wherein the interconnect insulating film is formed above a plasma silicon nitride film, the plasma silicon nitride film being formed above the underlying insulating film and functioning as a stopper for the anisotropic dry etching of the interconnect insulating film for forming the interconnect trench.

11. The method according to claim 2, wherein forming the interconnect insulating film with the plasma chemical vapor deposition technique specifies an output level of the high-frequency power supply to range between 10 to 30 MHz.

12. The method according to claim 2, wherein forming the interconnect insulating film with the plasma chemical vapor deposition technique specifies the output level of the low-frequency power supply to range between 300 to 500 kHz.

13. The method according to claim 1, wherein the anisotropic dry etching employs a mask formed in a sidewall transfer process.

14. The method according to claim 13, wherein the mask formed in the sidewall transfer process is obtained by forming a core material comprising a plasma silicon nitride film and forming an amorphous silicon film on a sidewall of the core material.

15. A semiconductor device, comprising:
an underlying insulating film;
an interconnect insulating film formed above the underlying insulating film, the interconnect insulating film including a film density being relatively greater at a lower side thereof and relatively less at an upper side thereof;
an interconnect trench formed into the interconnect insulating film, the interconnect trench including greater width at an upper side thereof compared to a lower side thereof;
a barrier metal film formed along an inner surface of the interconnect trench; and
an interconnect conductor filled into the interconnect trench over the barrier metal film.

16. The device according to claim 15, wherein the film density of the interconnect insulating film gradually varies so as to be relatively greater at the lower side thereof and relatively less at the upper side thereof.

17. The device according to claim 15, wherein the interconnect insulating film comprises plasma tetraethyl orthosilicate oxide film.

18. The device according to claim 15, wherein the underlying insulating film comprises plasma tetraethyl orthosilicate oxide film.

19. The device according to claim 15, wherein a plasma silicon nitride film is formed between the underlying insulating film and the interconnect insulating film, the plasma silicon nitride film functioning as a stopper when forming the interconnect trench.

20. The device according to claim 15, wherein the interconnect conductor comprises copper.
